(19) United States
(12) Patent Application Publication
(10) Pub. No.: US 2008/0029030 A1
(43) Pub. Date: Feb. 7, 2008

(54) Plasma Generator

(76) Inventors: Toshio Goto, Aichi-ken (JP); Masaru Hori, Aichi-ken (JP); Shoji Den, Aichi-ken (JP); Mikio Nagai, Aichi-ken (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(21) Appl. No.: 10/589,568

(22) PCT Filed: Jan. 26, 2005
(86) PCT No.: PCT/JP05/01003

§ 371 Date: Jul. 9, 2007

(30) Foreign Application Priority Data
Feb. 17, 2004 (JP) 2004-40628

(51) Int. Cl. H01L 21/205; H01L 21/304; H01L 21/3065; H05H 1/24

(52) U.S. Cl. 118/723 R

(57) ABSTRACT

[Object] To stably generate plasma at atmospheric pressure.

[Solving Means] There are provided a tubular casing 10 into which a gas and a microwave are introduced, a hole 30 provided in a bottom surface of this casing, and a columnar conductor 40 which is provided in an axis direction of the casing, a bottom surface of the conductor 40 having a contour placed inside the contour of the hole. A minute gap A formed between the contour of a bottom surface 41 of the conductor 40 and the contour of the hole, a coaxial waveguide formed of the conductor and the casing, and an insulating film 22 formed at least on a contour portion forming the hole at the minute gap are provided. In the structure described above, the microwave is guided to the minute gap by the coaxial waveguide, and the gas is made to pass through the minute gap, so that the gas is placed in a plasma state at the minute gap. The microwave is a pulse wave and is duty-controlled, and the contour portion forming the hole 30 is cooled with a cooling medium from the inside of an electrode 20. Accordingly, the increase in plasma temperature can be prevented, and as a result, stable plasma can be generated.

### TECHNICAL FIELD

The present invention relates to an apparatus which stably obtains plasma. The present invention particularly relates to an apparatus which stably obtains plasma using a microwave at atmospheric pressure (without being evacuated by a factor other than a gas flow). For example, the above apparatus may be used as an apparatus which decomposes a fluorocarbon gas used in a semiconductor etching process, a film-forming process, or the like and which recovers the above gas in the form of particles.

### BACKGROUND ART

In recent years, in an etching step and a film-forming step of a semiconductor process, plasma of a fluorocarbon gas has been used. For example, in order to increase the degree of integration of a semiconductor integrated circuit, an ultrafine fabrication technique and an epitaxial growth technique must be improved, and in particular, the improvement in ultrafine fabrication technique is absolutely necessary. In this ultrafine fabrication technique, improvement in process accuracy has been strongly desired so as to satisfies the requirements of a high aspect ratio, reduction in minimum line width of 0.1 μm or less by etching, and the like. As a highly efficient ultrafine fabrication technique used for a large area, plasma etching has attracted attention. This plasma etching performs etching using radicals, ions and the like in a plasma state. In particular, in an ultrafine selective etching process in which ultrafine etching of a SiO₂ film as an insulating film is stopped by an underlying Si layer, CF and CF₂ radicals, which are obtained by decomposition of CF₄ and C₄F₈, are used together with an Ar gas.

### DISCLOSURE OF INVENTION

However, fluorocarbon gases, such as CF₄, C₄F₈, and C₂F₆, used for a plasma etching and a film-forming technique have an extremely long life as compared to that of carbon dioxide and have an extremely high global warming potential. Hence, the use of the fluorocarbon gases may lead to environmental destruction, and the emission thereof into the atmosphere may be probably inhibited in future. However, development for recovering used fluorocarbon gases has not been well performed from various technical aspects. The inventors of the present invention succeeded in recovering fluorocarbon gases in the form of particles without generating carbon dioxide by the steps of generating plasma at atmospheric pressure using a micro-gap, and allowing fluorocarbon gases to pass through this plasma so that the gases are decomposed and synthesized into a polymer in the form of particles. In addition, since the technique itself that stably generates plasma at atmospheric pressure is an effective technique in various application fields, such as etching, film formation, machine processing, and cleaning, the inventors of the present invention have further carried out research on the mechanism that stably generates non-equilibrium plasma at atmospheric pressure. As the results of the research, in particular, the present invention provides an apparatus that can stably generate plasma, the application of which being unlimited.

A first object of the present invention is to stably generate plasma. In addition, a second object is, in particular, to stably generate non-equilibrium plasma using a microwave at atmospheric pressure (in a state in which an evacuation element is not intentionally used other than a gas flow) or at a pressure higher than atmospheric pressure. Furthermore, a third object is to make it possible to recover fluorocarbon gases in the form of particles by using stably generated plasma. A fourth object is to provide a plasma generation apparatus used for etching, film formation, machine processing, and the like.

It is to be understood that the objects described above are achieved by respective aspects of the present invention, and it is not to be understood that all the objects are achieved by each aspect of the present invention.

### MEANS FOR SOLVING THE PROBLEMS

To these ends, a plasma generation apparatus according to a first aspect of the present invention, comprises: an electrode composed of a conductor forming a minute gap which allows a gas generating plasma to pass therethrough and which increases an intensity of electric field of a guided microwave, wherein an insulating film is formed on a surface of at least a portion of the electrode, which forms the minute gap. That is, in the present invention, the insulating film is formed at least on the surface portion forming the minute gap at which plasma is formed. By this configuration, a state in which an electron temperature is higher than a gas temperature at atmospheric pressure, that is, non-equilibrium plasma, can be obtained.

That is, the present invention relates to an atmospheric non-equilibrium plasma generation apparatus.

In a second aspect of the present invention, the plasma generation apparatus according to the first aspect may further comprise: a casing composed of a conductor into which the microwave is introduced; and a bottom plate composed of a conductor which performs electromagnetic shielding at an end face of the casing opposite to that at which the microwave is introduced, wherein the minute gap is formed in the bottom plate. That is, according to the present invention, a resonator for the microwave is formed using a tubular body having a bottom and made of a conductor (a member forming the bottom may be formed integrally with or separately from a member forming a side surface). In an end face of the casing through which the microwave is introduced, an opening is electromagnetically provided, so that the gas and the like are prevented from flowing backward. For example, sealing is performed with a dielectric substance. In addition, by a bottom plate made of a conductor and the casing made of a conductor, the inside is electromagnetically isolated from the outside except for an introduction port of the microwave. In this bottom plate, the minute gap is formed. That is, the bottom plate itself is the electrode forming the minute gap. A power density of the microwave is increased by this minute gap. In addition, the casing is designed so that the gas is introduced through a certain place thereof and is guided to the minute gap. In this aspect of the present invention, the insulating film is formed on a surface of a portion, which forms the minute gap, of the bottom plate. Of course, the insulating film may be formed all over an outer and an inner surface of the casing and a side surface of the minute gap. The minute gap may have any shape such as a rectangular or a ring shape. The width of a slit may be optionally determined as long as it easily generates plasma. In general, the width is approximately 0.1 to 0.3 mm; however, it is not particularly limited.

In a third aspect of the present invention, the plasma generation apparatus according to the first aspect or the second aspect, may further comprise: a casing composed of a conductor into which the microwave is introduced; and a bottom plate composed of a conductor which performs electromagnetic shielding at an end face of the casing opposite to that at which the microwave is introduced, wherein the bottom plate is provided with a window, and the electrode is disposed at the bottom plate so as to close the window, whereby the minute gap is formed. The insulating film is provided on a surface of at least a portion, which forms the minute gap, of the electrode. Of course, the insulating film may be formed over the entire surface of the electrode.

According to a fourth aspect of the present invention, in the plasma generation apparatus according to one of the first to the third aspects, the electrode has a structure in which the electrode including a portion forming the minute gap is cooled from the inside of the electrode by a cooling medium. This structure is designed so that the cooling medium is circulated inside the electrode to cool the surface of the portion forming the minute gap. As the cooling medium, besides water, for example, Flourinate, Galden, or a cooling medium of −100° C. may be used.

A plasma generation apparatus according to a fifth aspect of the present invention, comprises: a tubular casing into which a gas and a microwave are introduced; a hole provided in a bottom surface of the casing; a columnar conductor provided in an axis direction of the casing and having a bottom surface contour inside a contour of the hole; a minute gap formed between the contour of the bottom surface of the conductor and the contour of the hole; a coaxial waveguide formed by the conductor and the casing; and an insulating film formed at least on a contour portion forming the hole which forms the minute gap, wherein the microwave is introduced into the minute gap by the coaxial waveguide, and the gas is allowed to pass through the minute gap, whereby the gas is placed in a plasma state at the minute gap.

In the present invention, the pressure is not particularly limited; however, the plasma generation apparatus of the present invention is effectively used at atmospheric pressure (state in which evacuation is not intentionally performed except that caused by a flow rate) or a higher than that, such as a pressure of 2 atm (the condition is also applied to the first to the fourth aspects of the present invention). That is, although it is difficult to stably obtain plasma at atmospheric pressure, when the apparatus of the present invention is used, stable plasma can be obtained at atmospheric pressure. The central conductor and the casing made of a conductor form a waveguide, the microwave is guided along this waveguide, and energy density of the microwave is increased at the minute gap. As a result, when a gas is supplied to the minute gap, plasma is obtained at the minute gap. The contour of the hole formed at the central portion of the bottom surface of the casing made of a conductor and the contour of the bottom surface of the central conductor form the minute gap. A place at which the distance between the central conductor and the bottom surface of the casing is minimized is defined as the minute gap. According to the present invention, the insulating film is formed at least on the contour portion, which is along the hole, of the bottom surface of the casing. That is, according to the present invention, the portion of the bottom surface of the casing, which is along the periphery of the hole and on which an electric field is most concentrated, is covered with the insulating film. Of course, the front surface and the rear surface of the bottom of the casing and the side surface of the hole may all be covered with the insulating film. For the insulating film, for example, ceramics such as Al₂O₃, SiO₂, Si₂O₃, and TiO, BN and diamond may be used. In addition, any material may be used as long as it is a high-melting-point insulating material (the insulating film material is also applied to the first to the fourth aspects of the present invention). The conductor present in the casing has a function of inducing the microwave in cooperation with the casing. When one hole is provided in the bottom surface of the casing, the conductor is preferably provided along the central axis of the tubular casing. When a plurality of holes is formed, the conductor may be placed at an optional position as long as the microwave is guided to a plurality of minute gaps. In a cross-section of the hole parallel to the axis direction of the casing, the side surface of the hole preferably has a tapered shape such that an opening area is decreased toward the outside of the casing. The angle at the front end of the tapered portion is preferably in the range of 30° to 60°. However, a tapered shape may also be used in which the opening area is increased toward the outside of the hole. Hence, an angle of the front end in the range of 30° to 150° may also be used (the structure of the taper and the preferable angle thereof are also applied to the first to the fourth aspects of the present invention). The frequency of the microwave is not particularly limited; however, a frequency of 2.45 GHz may be used by way of example. As the waveguide of the microwave to the casing, any type such as a rectangular waveguide or a coaxial cable may be used; however, when a rectangular waveguide is used, the transmission mode is converted at an inlet of the casing.

When the above structure is used, the state in which the electron temperature is higher than the gas temperature at atmospheric pressure, that is, non-equilibrium plasma, can be obtained.

That is, according to the present invention, an atmospheric non-equilibrium plasma generation apparatus can be obtained.

In a sixth aspect of the present invention, the plasma generation apparatus according to the fifth aspect, may further comprise an insulating film which is formed at least on a portion, which forms the minute gap, of the conductor. That is, in the present invention, the insulating film is formed on the portion of the conductor, which faces the hole and which forms the minute gap. Of course, the insulating film may be provided all over the surface of the conductor. As the material for the insulating film, for example, the afore-mentioned ceramics etc., may be used.

According to a seventh aspect of the present invention, in the plasma generation apparatus according to one of the first to the sixth aspects, the bottom surface of the conductor is cooled from the inside thereof. By circulating water or the like inside the conductor, the temperature of the conductor is prevented from being increased. In this step, a cooling medium must be circulated to the front end of the conductor.

According to an eighth aspect of the present invention, in the plasma generation apparatus according to one of the fifth to the seventh aspects, a hole portion of the bottom surface of the casing is cooled. By circulating water or the like in the hole portion of the casing, the temperature of the hole portion is prevented from being increased. In this step, a cooling medium must be circulated to the front end which reaches the hole.

According to a ninth aspect of the present invention, in the plasma generation apparatus according to one of the first to the eighth aspects, the microwave is applied in the form of periodic pulses. When the cycle and the duty ratio of the microwave are changed, the power density at the minute gap can be controlled. In addition, when the plasma temperature and the temperature of a member forming the minute gap are measured, and the duty ratio and the cycle period of the microwave are feed-back controlled so as to obtain a predetermined temperature, the temperature control can be ideally performed, and as a result, stable plasma can be generated.

According to a tenth aspect of the present invention, in the plasma generation apparatus according to one of the first to the ninth aspects, the plasma is plasma of argon gas or plasma of nitrogen gas. By the structure of the present invention, plasma of argon gas and plasma of nitrogen gas can be stably obtained. When a fluorocarbon gas is introduced into this plasma, after decomposition and synthetic polymerization, the fluorocarbon gas can be converted into fine particles without generating carbon dioxide.

### ADVANTAGES

According to the first to the fourth aspects of the present invention, since the insulating film is provided at least on the minute gap portion, even when the power density of an introduced microwave is increased at the minute gap, arc discharge is prevented from being generated at the minute gap. As a result, plasma can be stably generated. In particular, it is difficult to obtain the state in which the electron temperature is higher than the gas temperature at atmospheric pressure, that is, a non-equilibrium state; however, according to the present invention, non-equilibrium plasma could be obtained at atmospheric pressure. Since the electron density of atmospheric non-equilibrium plasma is approximately 10¹⁵/cm³, which is approximately 3 orders of magnitude larger than that of low-pressure high density plasma, high-density radicals and ions can be generated, and as a result, a high rate process can be performed; hence, the atmospheric non-equilibrium plasma is a significantly effective technique for decomposition and synthesis of etching gases.

According to the fifth aspect of the present invention, since the insulating film is provided at least on the minute gap portion of the bottom surface of the conductive casing, the portion forming the hole, arc discharge is prevented from being generated at the minute gap. As a result, plasma can be stably generated. As the above aspects of the present invention, in particular, it is difficult to obtain the state in which the electron temperature is higher than the gas temperature at atmospheric pressure, that is, a non-equilibrium state; however, according to the present invention, non-equilibrium plasma could be obtained at atmospheric pressure. Since the electron density of atmospheric non-equilibrium plasma is approximately 10¹⁵/cm³, which is approximately 3 orders of magnitude larger than that of low-pressure high density plasma, high-density radicals and ions can be generated, and as a result, a high rate process can be performed; hence, the atmospheric non-equilibrium plasma is a significantly effective technique for decomposition and synthesis of etching gases.

According to the sixth aspect of the present invention, the insulating film is provided at least on a portion of the bottom surface, which forms the minute gap, of the conductor which is provided inside of the casing. That is, the two conductor (electrode) portions facing each other and forming the minute gap are covered with the insulating films, and as a result, arc discharge can be very effectively prevented. Consequently, significantly stable plasma could be generated.

According to the seventh and the eighth aspects of the present invention, when the two conductors (electrodes) forming the minute gap are cooled with water or another cooling medium, the temperature of plasma generated at the minute gap was prevented from being increased, and as a result, a stable temperature could be obtained by control. Since the temperature of plasma can be stably controlled, a substrate processed by plasma is protected from a thermal influence, and the quality thereof can be improved. In addition, when a fluorocarbon gas is made to flow in plasma for decomposition and synthesis, stable polymerization reaction can be realized by stable temperature control, and as a result, recovery efficiency of the fluorocarbon gas in the form of particles can be improved.

According to the ninth aspect of the present invention, since the microwave is applied in the form of periodic pulses, when the pulse cycle and the duty ratio are controlled, the electric field of the microwave at the minute gap can be controlled at a predetermined value. Since plasma is stabilized, the temperature thereof can be controlled, and the amount of plasma thus generated can be controlled, processing using plasma and reaction with plasma can be more accurately controlled.

According to the tenth aspect of the present invention, plasma is generated by argon gas or nitrogen gas. By the apparatus of the present invention, plasma could be stably generated at atmospheric pressure even by argon gas or nitrogen gas. In addition, when a fluorocarbon gas is introduced into plasma of this gas, recovery in the form of particles could be performed at a high efficiency.

### BRIEF DESCRIPTION OF THE DRAWINGS

FIG. 1 is a view showing the structure of a plasma generation apparatus of a particular example according to the present invention.

FIG. 2 is a graph showing the measurement results of optical absorption properties which identifies the temperature of plasma generated in the apparatus.

FIG. 3 is a graph showing the measurement results of a plasma temperature with time from the application of microwave in the apparatus.

FIG. 4 is a graph showing the measurement results of a plasma temperature vs the duty ratio of microwave in the apparatus.

FIG. 5 is a graph showing the measurement results of a plasma temperature vs an electric power of microwave in the apparatus.

FIG. 6 is a graph showing the measurement results of an electrode temperature vs an electric power of microwave in the apparatus.

FIG. 7 is a view showing the structure of a plasma generation apparatus of another particular example according to the present invention.

### REFERENCE NUMERALS

10 casing

11 bottom surface

20 electrode

30 hole

60 exhaust chamber

110 casing

300 hole

320 insulating film

120 bottom plate

410 susceptor

420 semiconductor substrate

A minute gap

### BEST MODE FOR CARRYING OUT THE INVENTION

The best mode for carrying out the present invention will be described. Embodiments will be described in a particular manner in order to facilitate the understanding of the inventive concept, and hence it is not to be understood that the present invention is limited to the following embodiments.

### Example 1

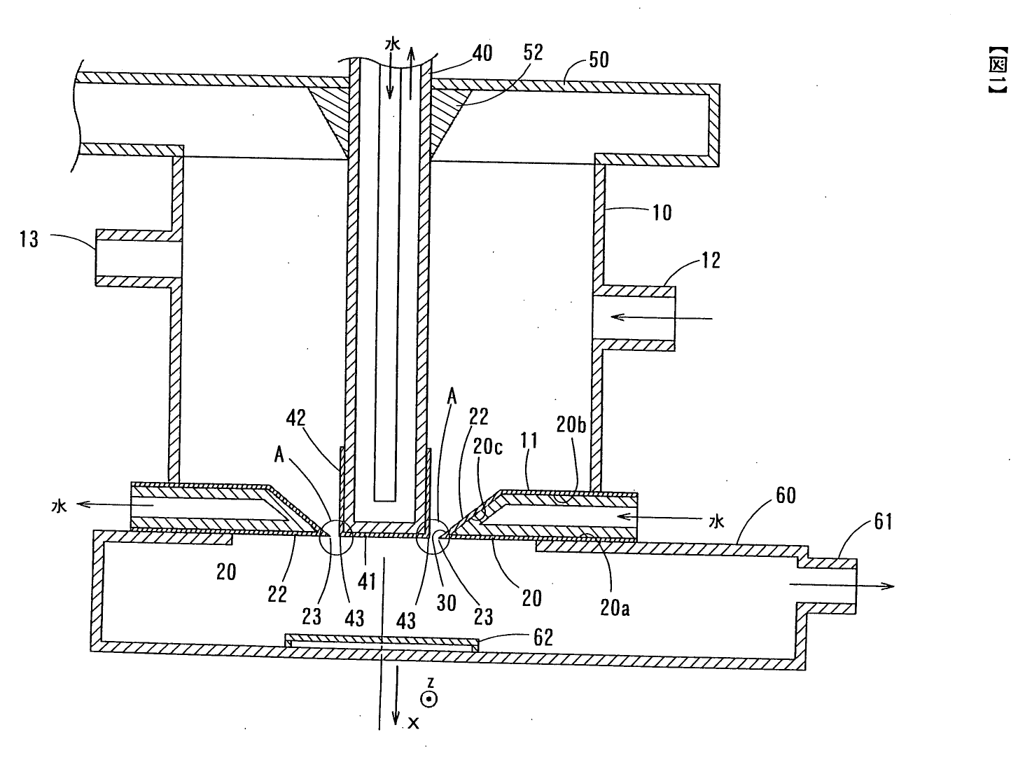

FIG. 1 shows an example of a plasma generation apparatus used for decomposition and synthesis of a CF₄ gas. A tubular casing 10 is formed of copper, and for a bottom surface 11 thereof, an electrode 20 composed of a disc-shaped conductor is provided. A circular hole 30 having a radius of 8 mm is provided in the central portion of the disc-shaped electrode 20. The side-surface cross-section of the electrode 20 is formed to have a taper so that the diameter of the hole 30 is decreased in the outside direction (in the x-axis direction).

An outer surface 20a, an inner surface 20b and a side surface 20c of this electrode 20 are covered with an insulating film 22 composed of Al₂O₃ having a thickness of 150 μm. In addition, the electrode 20 is formed so that cooling water is supplied therein for circulation and reaches the portion forming the hole 30 at the front end, that is, is formed so as to cool the hole 30 of the electrode 20.

A central conductor 40 is provided along the central axis of the casing 10 and is located at the center of the hole 30, and a front end surface 41 of the central conductor 40 is disposed at the same height (the same x axis coordinate) as that of the outer surface 20a of the electrode 20. In addition, an outer surface of a front end portion of the central conductor 40 is covered with an insulating film 42 of Al₂O₃ having a thickness of 150 μm. In this configuration, a minute gap A is formed between a circular contour 23 of a front end portion which forms the hole 30 of the electrode 20 and a circular contour 43 of the front end surface 41 (bottom surface) of the central conductor 40. The width of the minute gap A is in the range of 0.1 to 0.2 mm. In the space inside this central conductor 40 including a front end of the space, cooling water is circulated so as to cool the front end portion and the front end surface 41 of the central conductor 40.

In addition, on the casing 10, a waveguide 50 for guiding a microwave into the casing 10 is provided, and the microwave guided by this waveguide 50 is converted from a waveguide mode to a coaxial mode by a mode converter 52 and is then transmitted to the minute gap A side. The casing 10 and the electrode 20 are both grounded. The microwave supplied by the structure as described above is concentrated at the minute gap A, and as a result, the electric field density at the minute gap A is maximized.

In the side surface of the casing 10, a gas inlet 12 is provided, and from this gas inlet 12, a gas for generating plasma is supplied. In this example, a He gas was used. In the other side surface of the casing 10, a gas induction port 13 is provided, and from this gas induction port 13, a fluorocarbon gas is introduced. In this example, a CF₄ gas was used.

Under the electrode 20, an exhaust chamber 60 is provided and is formed so that gases flowing through the gas inlets 12 and 13 are made to pass through the minute gap A by evacuation from an exhaust hole 61. In addition, a transport device 62, which collects generated particles and transports them outside the exhaust chamber 60, is provided in the exhaust chamber 60 and under the minute gap A. The transport device 62 is formed so that particles are transported in the direction perpendicular to the plane of FIG. 1 (z axis direction) and are recovered from the exhaust chamber 60.

The apparatus described above was operated as described below. Cooling water was circulated inside the central conductor 40 and inside the electrode 20. Next, from the waveguide 50, a microwave was supplied having a frequency of 2.45 GHz, a peak electric power of 300 W, a pulse repetition frequency of 10 kHz, and a duty ratio of 50%. The pressure inside the casing 10 was 1 atom, and the exhaust amount from the exhaust port 61 was controlled so as to introduce a He gas at a flow rate of 2 L/min into the casing 10 from the gas inlet port 12. Under the conditions described above, He plasma was stably generated at the minute gap A. Next, the exhaust amount from the exhaust port 61 was controlled so as to introduce a CF₄ gas at a flow rate of 2 L/min into the casing 10 from the inlet port 13. As a result, at the minute gap A, by decomposition of CF₄ and polymerization reaction, particles of polytetrafluoroethylene were generated, then fell on the transport device 62, and were accumulated. In this step, the generation of carbon dioxide was not observed. The decomposition rate of CF₄ was 80% or more.

### Example 2

Next, by using the above apparatus, an Ar gas and a N₂ gas were used instead of a He gas. Since a He gas is expensive, when an Ar gas and a N₂ gas can be used, significant industrial advantages can be obtained. Hence, first of all, by using an apparatus in which the insulating film 22 and the insulating film 42 are not formed on the metal electrode 20 and the central conductor 40, respectively, experiments were each carried out by continuous supply of a microwave having an electric power of 200 W. However, the electrode 20 and the central conductor 40 were cooled by circulating cooling water, and the pressure was set to atmospheric pressure. Three experiments, that is, an experiment in which a He gas was supplied at a flow rate of 2 L/min, an experiment in which an Ar gas was supplied at a flow rate of 2 L/min, and an experiment in which a N₂ gas was supplied at a flow rate of 2 L/min, were carried out. As a result, in the case of a He gas, the generation of stable plasma was observed, and on the other hand, in the cases of an Ar gas and a N₂ gas, it was difficult to uniformly generate stable plasma at the ring-shaped minute gap A.

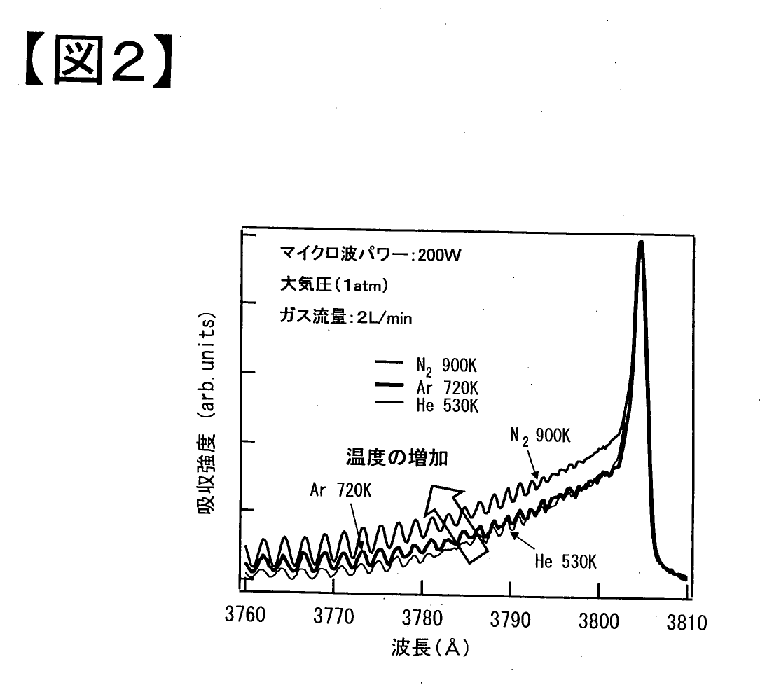

Next, an apparatus was used in which the insulating film 22 was formed on the side surface, the outer surface, and the inner surface of the metal electrode 20, and the insulating film 42 was formed on the surface of the front end portion of the central conductor 40. Next, as described above, three types of gases were separately supplied at a flow rate of 2 L/min. By the three types of gases, stable plasma was observed at the ring-shaped minute gap A. In order to investigate the plasma state, a gas temperature was measured by an ICCD camera and an electrode temperature was measured by FTIR. The emission spectrum was measured by an ICCD camera, and the gas temperature of plasma was obtained from the second positive band emission. That is, the coefficient was determined so that the simulation spectrum coincides with the measured spectrum, and the rotation temperature was obtained. This rotation temperature was regarded as the plasma temperature. In the following results, the values obtained for the rotation temperature are all shown as the plasma temperature. The results are shown in FIG. 2. The plasma temperatures of a He gas, an Ar gas, and a N₂ gas were 350K, 720K, and 900K, respectively, and the relationship thereof was represented by He<Ar<N₂. While the electrode temperature and the plasma temperature are detected, they are preferably maintained constant by controlling the duty ratio of microwave using a feedback circuit.

In addition, after the insulating film 42 was not formed on the surface of the central conductor 40, and the insulating film 22 was only formed on the electrode 20 as described above, an experiment similar to that described above was performed. In this case, the results approximately similar to those described above were obtained although the stability was slightly inferior. In addition, after the insulating film 42 was formed on the surface of the central conductor 40, and the insulating film 22 was not formed on the electrode 20, an experiment similar to that described above was performed. In this case, relatively stable plasma was also observed although the stability was more degraded than that described above. Accordingly, it is most preferable that the insulating films be provided for both the central conductor 40 and the electrode 20.

### Example 3

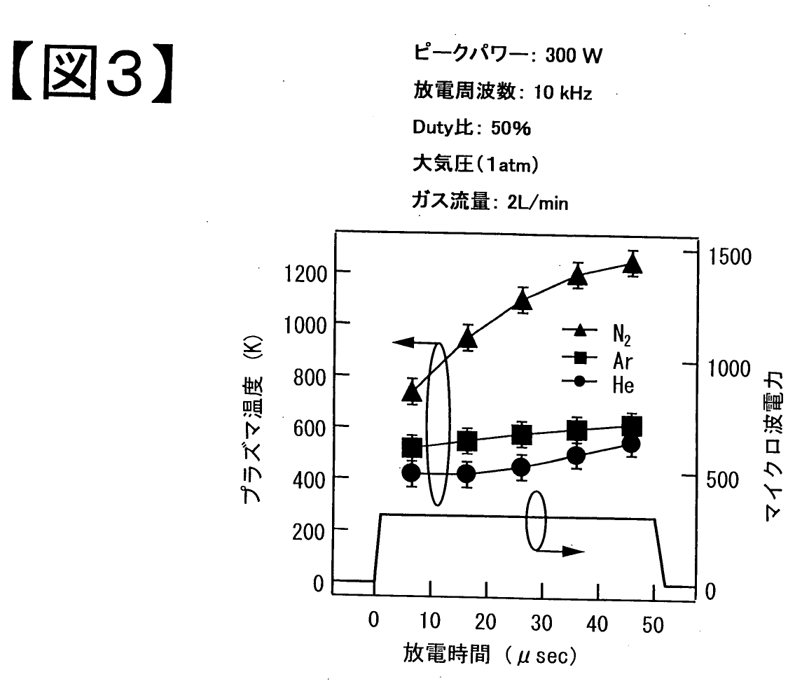

Next, the plasma temperature with time from the application of microwave was measured in a manner similar to that in Example 2. The results are shown in FIG. 3. A microwave having a frequency of 2.45 GHz and an electric power of 300 W was introduced into the casing 10 under the condition similar to that in Example 2. Subsequently, He, Ar, and N₂ gases were separately introduced, and the change in plasma temperature was separately measured. From the results shown in FIG. 3, it is understood that although the temperature increase is not observed in the cases of He and Ar, the temperature is rapidly increased in the case of N₂. From the above measurement results, the inventors of the present invention assumed that in order not to increase the plasma temperature, when a pulse wave is used as the microwave, and the cycle period and the pulse width are controlled so as to control the duty ratio, the plasma is cooled while the microwave is not applied. Accordingly, the inventors of the present invention conceived from this result that when a pulse wave is used as the microwave, and frequency control and duty control are performed, the increase in plasma temperature is suppressed, and stable plasma having a constant temperature can be obtained; hence the following experiments were carried out.

### Example 4

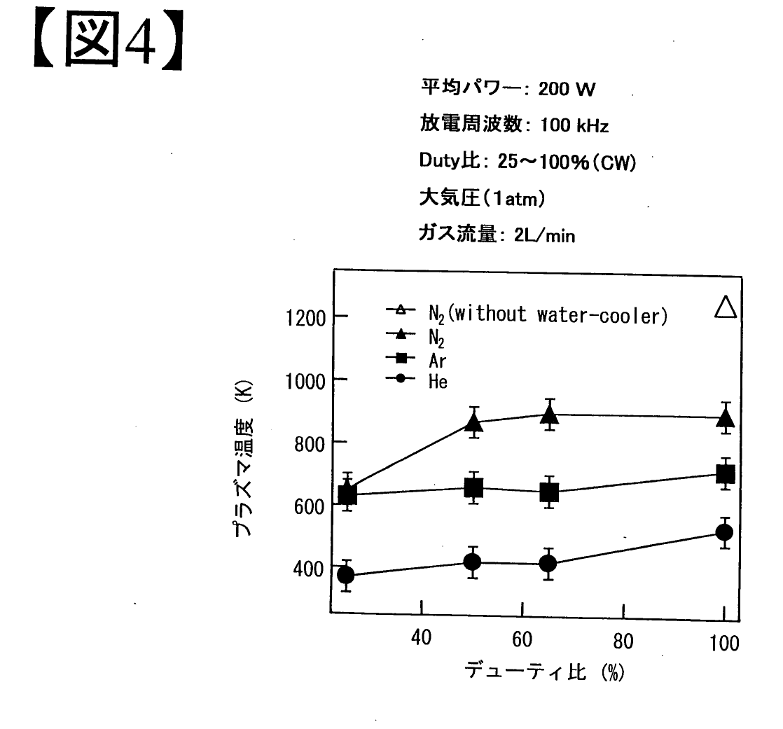

Next, by using a microwave having a frequency of 2.45 GHz, an average electric power of 200 W, and a pulse period of 100 kHz, the plasma temperature of each gas was measured with the change of the duty ratio. The other conditions were the same as those in Example 2. The measurement results are shown in FIG. 4. One pulse having a pulse period of 100 KHz and a duty ratio of 50% indicates 5 μs after the application of the microwave in terms of time shown in FIG. 3. In particular, it is understood that the plasma temperature of N₂ is stabilized at approximately 900K. In addition, since the plasma temperature of N₂ is increased to 1,300K when the microwave is applied for 50 μs, as shown in FIG. 3, it is understood that in the case of a N₂ gas, the duty control of the microwave is significantly important in order to control the plasma temperature. In particular, in the case of N₂, since an effect of suppressing the increase in temperature is significant, the combination of the duty control of microwave and a N₂ gas is specific.

### Example 5

Next, in Example 4, in the case in which the duty ratio was set to 100% (continuous electricity supply) and cooling was not performed for the electrode 20 and the central conductor 40, the plasma temperature was measured by introducing a N₂ gas. As shown in FIG. 4, when the electrode 20 and the central conductor 40 are cooled, the temperature was 900K; however, when cooling was not performed, the temperature was increased to 1,250K. From this result, it is understood that cooling of the central conductor 40 and the electrode 20 is effective for the control of the plasma temperature. In particular, in the case of N₂, since an effect of suppressing the increase in temperature is significant, the combination of the duty control of microwave and a N₂ gas is specific. In addition, the cooling structure of the electrode, the duty control of microwave, and the coating of the minute gap portion with the insulating film are particularly effective to control the plasma temperature, and hence these three elements form a specific combination.

### Example 6

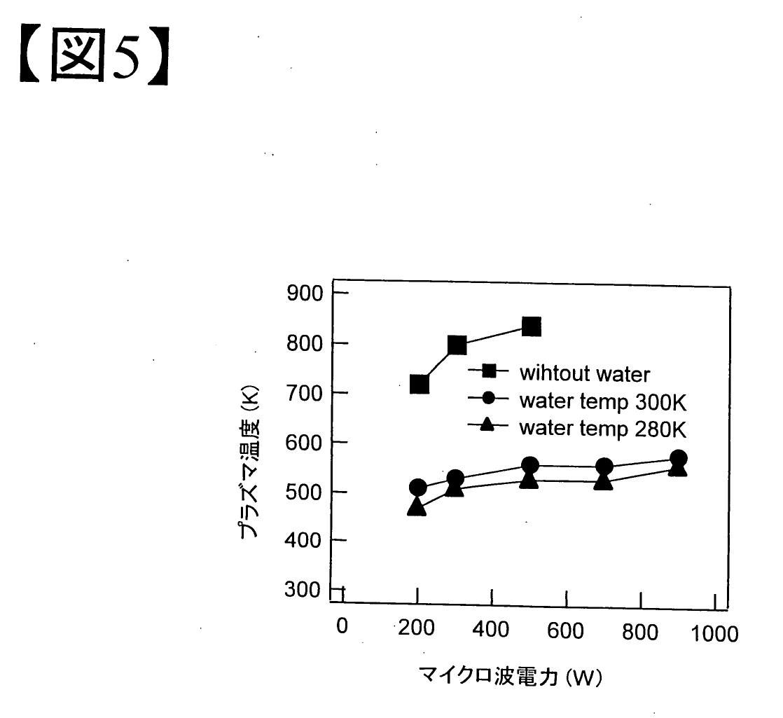

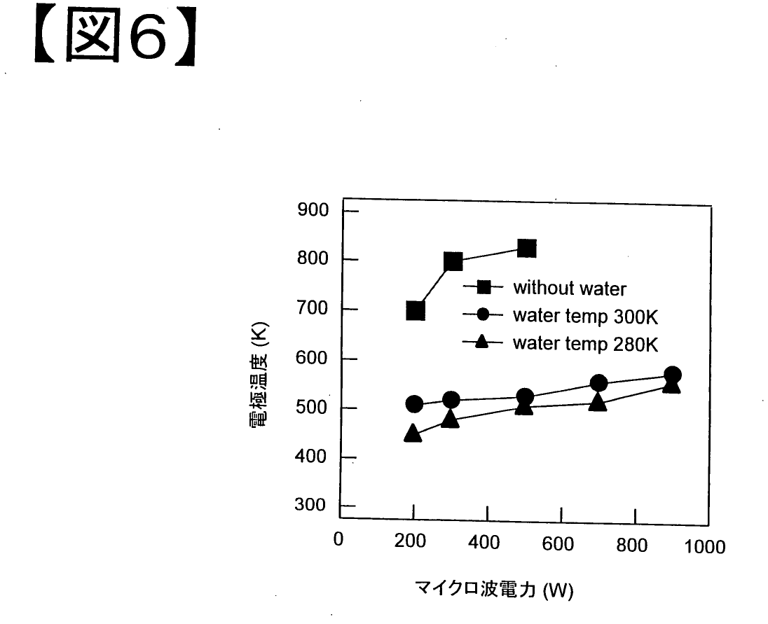

According to Example 4, it is understood that water cooling of the central conductor 40 and the electrode 20 is effective for the control of the plasma temperature; hence, for further investigation, the relationship between the plasma temperature and the temperatures (when the temperatures of the two described below are not necessarily discriminated from each other, the temperatures are simply referred to as “electrode temperature”) of the central conductor 40 and the electrode 20 (when the above two are not necessarily discriminated from each other, they are simply referred to as “electrode”) was measured. However, in this experiment, gases were not made to flow and were enclosed in a closed space. That is, the experiment was performed while the exhaust chamber 60 shown in FIG. 1 was insolated from the outside. A microwave was continuously supplied under the conditions in which a He gas was enclosed in a chamber (formed by the casing 10 and the exhaust chamber 60) at 1 atmosphere. The plasma temperature and the electrode temperature were measured with the change in electric power of the microwave. The plasma temperature is shown in FIG. 5, and the electrode temperature is shown in FIG. 6. Three measurements were performed in which cooling was performed at a water temperature of 280K and 300K, and cooling was not performed at all, and it is understood that even when the electric power of the microwave is changed, the plasma temperature well coincides with the electrode temperature. In addition, it is understood that when the electrode is cooled, the plasma temperature is decreased by 200K or more as compared to that obtained when the electrode is not cooled. The reason the plasma temperature coincides with the electrode temperature even when the electrode is not cooled is believed that the increase in plasma temperature of a He gas by electric power of the microwave is relatively small. From these measurement results, it is understood that the cooling of the electrode is significantly effective to control the plasma temperature.

### Example 7

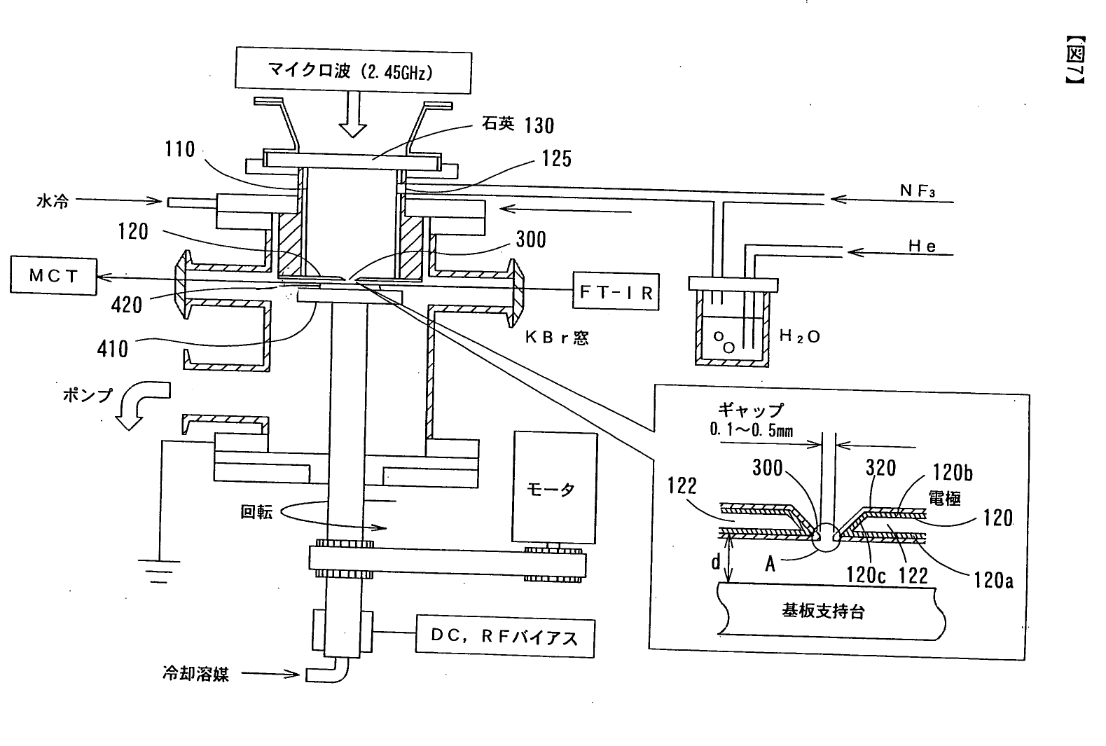

The plasma generation apparatus can be designed to have the structure shown in FIG. 7. A resonator is composed of a casing 110 formed from a tubular conductor having a diameter of 100 mm and a bottom plate 120 formed from a conductor. In the central portion of the bottom plate 120, a rectangular hole (slit) 300 having a width of 0.1 to 0.2 mm and a length of 30 mm is formed. This hole 300 has a tapered cross-section as shown in the figure. Cooling water 122 is circulated inside the bottom plate 120 including a part thereof forming the hole 300. The cooling water 122 is circulated and reaches the tapered side wall forming the hole 300. In addition, an insulating film 320 is formed on an outer surface 120a, an inner surface 120b, and a side surface 120c of the bottom plate 120. A material for the insulating film is similar to that described in the above example. The upper end surface of the casing 110 is sealed by a quartz plate 130 so that a gas introduced into the casing 110 is not allowed to flow backward. The microwave passes through this quartz plate 130 and is then introduced inside the casing 110 which is the resonator, and the power density is increased at the minute gap A formed by the hole 300 provided in the bottom plate 120. A NF₃ gas and a He gas passing through H₂O are introduced into the casing 110 via a gas inlet 125 and reach the minute gap A.

In this step, by the electric power of the microwave, He plasma is generated at the minute gap A portion, NF₃ and H₂O are decomposed, and F radicals, H radicals, OH radicals, F ions, F₂ molecules, HF molecules, and the like are generated. By the radicals and the like, a semiconductor substrate placed on a rotary susceptor 410 provided under the hole 300 is etched. The plasma thus generated is observed by an absorption spectroscopy using laser and is controlled to be placed in a most preferable state.

As is the case of the above examples, for example, the microwave may be a continuous wave or a pulse wave, and in the case of a pulse wave, the plasma temperature can be controlled by the cycle period and the duty ratio of the pulse.

### Application Fields of the Invention

The present invention provides an apparatus stably generating plasma. In particular, the apparatus can be advantageously used at atmospheric pressure. In semiconductor etching, film-forming process, machining, cleaning, surface reforming, and the like, which use plasma, it is not necessary to evacuate a process chamber, and hence this apparatus is particularly advantageous. Since the electron density of atmospheric plasma is approximately 10¹⁵/cm³, which is approximately 3 orders of magnitude larger than that of low-pressure high density plasma, high-density radicals and ions can be generated, and hence a high rate process can be performed. In addition, since gases can be decomposed and polymerized by plasma, the recovery of exhaust gas in the form of particles and the formation of a fluorocarbon gas and radicals thereof from graphite and a F₂ gas can be advantageously performed.

### INDUSTRIAL APPLICABILITY

According to the present invention, plasma effectively used for semiconductor processes and the like can be stably supplied. Hence, in a semiconductor device manufacturing plant, this technique is significantly effective.

As has thus been described, since individual constituent elements can be separated and extracted, when extracted constituent elements are independently used in combination, one aspect of the invention may be formed. When an optional constituent element disclosed in Claims is eliminated, one aspect of the present invention may also be formed.

1. A plasma generation apparatus comprising: an electrode composed of a conductor forming a minute gap which allows a gas generating plasma to pass therethrough and which increases an electron density of a guided microwave, wherein an insulating film is formed on a surface of at least a portion of the electrode, which forms the minute gap.

2. The plasma generation apparatus according to claim 1, further comprising: a casing composed of a conductor into which the microwave is introduced; and a bottom plate composed of a conductor which performs electromagnetic shielding at an end face of the casing opposite to that at which the microwave is introduced, wherein the minute gap is formed in the bottom plate.

3. The plasma generation apparatus according to claim 1, further comprising: a casing composed of a conductor into which the microwave is introduced; and a bottom plate composed of a conductor which performs electromagnetic shielding at an end face of the casing opposite to that at which the microwave is introduced, wherein the bottom plate is provided with a window, and the electrode is disposed at the bottom plate so as to close the window, whereby the minute gap is formed.

4. The plasma generation apparatus according to claim 1, wherein the electrode has a structure in which the electrode including a portion forming the minute gap is cooled from the inside of the electrode by a cooling medium.

5. A plasma generation apparatus comprising:
a tubular casing into which a gas and a microwave are introduced;
a hole provided in a bottom surface of the casing;
a columnar conductor provided in an axis direction of the casing and having a bottom surface contour inside a contour of the hole;
a minute gap formed between the contour of the bottom surface of the conductor and the contour of the hole;
a coaxial waveguide formed by the conductor and the casing; and
an insulating film formed at least on a contour portion forming the hole which forms the minute gap,
wherein the microwave is introduced into the minute gap by the coaxial waveguide, and the gas is allowed to pass through the minute gap, whereby the gas is placed in a plasma state at the minute gap.

6. The plasma generation apparatus according to claim 5, further comprising an insulating film which is formed at least on a portion, which forms the minute gap, of the conductor.

7. The plasma generation apparatus according to claim 1, wherein the bottom surface of the conductor is cooled from the inside thereof.

8. The plasma generation apparatus according to claim 1, wherein a hole portion of the bottom surface of the casing is cooled.

9. The plasma generation apparatus according to claim 1, wherein the microwave is applied in the form of periodic pulses.

10. The plasma generation apparatus according to claim 1, wherein the plasma is plasma of argon gas or plasma of nitrogen gas.

11. The plasma generation apparatus according to claim 2, further comprising: a casing composed of a conductor into which the microwave is introduced; and a bottom plate composed of a conductor which performs electromagnetic shielding at an end face of the casing opposite to that at which the microwave is introduced, wherein the bottom plate is provided with a window, and the electrode is disposed at the bottom plate so as to close the window, whereby the minute gap is formed.

12. The plasma generation apparatus according to claim 2, wherein the electrode has a structure in which the electrode including a portion forming the minute gap is cooled from the inside of the electrode by a cooling medium.

13. The plasma generation apparatus according to claim 3, wherein the electrode has a structure in which the electrode including a portion forming the minute gap is cooled from the inside of the electrode by a cooling medium.

14. The plasma generation apparatus according to claim 2, wherein the bottom surface of the conductor is cooled from the inside thereof.

15. The plasma generation apparatus according to claim 3, wherein the bottom surface of the conductor is cooled from the inside thereof.

16. The plasma generation apparatus according to claim 4, wherein the bottom surface of the conductor is cooled from the inside thereof.

17. The plasma generation apparatus according to claim 5, wherein the bottom surface of the conductor is cooled from the inside thereof.

18. The plasma generation apparatus according to claim 6, wherein the bottom surface of the conductor is cooled from the inside thereof.

19. The plasma generation apparatus according to claim 6, wherein a hole portion of the bottom surface of the casing is cooled.

20. The plasma generation apparatus according to claim 7, wherein a hole portion of the bottom surface of the casing is cooled.
